(19) United States
(12) Patent Application Publication
(10) Pub. No.: US 2024/0234092 A9
(43) Pub. Date: Jul. 11, 2024

(54) FREQUENCY-VARIABLE POWER SUPPLY AND PLASMA PROCESSING APPARATUS

(71) Applicant: Tokyo Electron Limited, Tokyo (JP)

(72) Inventor: Kazushi KANEKO, Nirasaki City (JP)

(21) Appl. No.: 18/382,809

(22) Filed: Oct. 23, 2023

(30) Foreign Application Priority Data
Oct. 24, 2022 (JP) 2022-170045

(51) Int. Cl. H01J 37/32

(52) U.S. Cl. CPC H01J 37/32165; H01J 37/32183

(57) ABSTRACT

A frequency-variable power supply that outputs radio-frequency (RF) waves of a set frequency and includes an operation part configured to calculate a correction value according to each of a plurality of frequencies within an outputtable frequency range.

### CROSS-REFERENCE TO RELATED APPLICATION

This application is based upon and claims the benefit of priority from Japanese Patent Application No. 2022-170045, filed on Oct. 24, 2022, the entire contents of which are incorporated herein by reference.

### TECHNICAL FIELD

The present disclosure relates to a frequency-variable power supply and a plasma processing apparatus.

### BACKGROUND

Disclosed is a plasma processing apparatus in which radio-frequency waves are generated by using waveform data including a set frequency component, a distortion component imparted to the radio-frequency waves is extracted in a path through which the radio-frequency waves are transmitted, and the waveform data is corrected by synthesizing an antiphase component of the distortion component with the set frequency component (Patent Document 1).

### PRIOR ART DOCUMENTS

### Patent Documents

Patent Document 1: Japanese Patent Laid-Open Publication No. 2017-228558

### SUMMARY

According to one embodiment of the present disclosure, there is provided a frequency-variable power supply that outputs radio-frequency (RF) waves of a set frequency and includes an operation part configured to calculate a correction value according to each of a plurality of frequencies within an outputtable frequency range

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view illustrating an example of a plasma processing system according to an embodiment of the present disclosure.

FIG. 2 is a block diagram illustrating an example of a functional configuration of a modulator according to the embodiment.

FIG. 3 is a block diagram illustrating an example of a functional configuration of a demodulator according to the embodiment.

FIG. 4 is a block diagram illustrating an example of connections when acquiring a power command value Mf and a Pf conversion value k1.

FIG. 5 is a view illustrating examples of single-peak waveforms of traveling wave power.

FIG. 6 is a view illustrating an example of a relationship between a power setting Pset and the power command value Mf at each frequency.

FIG. 7 is a graph illustrating an example of a relationship between the power setting Pset and the power command value Mf at a specific frequency.

FIG. 8 is a view illustrating an example of a relationship between the power setting Pset and the Pf conversion value k1 at each frequency.

FIG. 9 is a view illustrating an example of frequency characteristics of the relationship between the power setting Pset and the Pf conversion value k1.

FIG. 10 is a block diagram illustrating an example of connections when acquiring a Pr conversion value k3.

FIG. 11 is a view illustrating examples of single-peak waveforms of reflected wave power.

FIG. 12 is a view illustrating an example of a relationship between the power setting Pset and the Pr conversion value k3 at each frequency.

FIG. 13 is a view illustrating an example of frequency characteristics of the relationship between the power setting Pset and the Pr conversion value k3.

FIG. 14 is a block diagram illustrating an example of a functional configuration from an operation part to a plasma load according to the embodiment.

FIG. 15 is a flowchart illustrating an example of a calibration process according to the embodiment.

FIG. 16 is a flowchart illustrating an example of a correction process according to the embodiment.

FIG. 17 is a flowchart illustrating an example of a calculation process of a traveling wave power Pf.

FIG. 18 is a flow chart illustrating an example of a calculation process of a reflected wave power Pr.

FIG. 19 is a flowchart illustrating an example of a correction process of amplifier distortion.

FIG. 20 illustrates a view illustrating an example of extracting the amplifier distortion and generating amplifier distortion correction values.

FIG. 21 is a view illustrating examples of powers and phase differences from a set waveform to a corrected output waveform.

FIG. 22 is a flowchart illustrating an example of a cancellation process of reflection.

FIG. 23 is a view illustrating an example of extracting the reflection and generating reflection correction values.

FIG. 24 is a view illustrating an example of synthesizing reflection correction values.

FIG. 25 is a view illustrating an example of synthesizing the traveling wave power Pf and the reflection correction values.

FIG. 26 is a block diagram illustrating an example of a functional configuration from an operation part to a plasma load according to Modification 1.

FIG. 27 is a block diagram illustrating an example of a functional configuration from an operation part to a plasma load according to Modification 2.

FIG. 28 is a block diagram illustrating an example of a functional configuration from an operation part to a plasma load according to Modification 3.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Embodiments of a frequency-variable power supply and a plasma processing apparatus disclosed herein will be described in detail below with reference to the drawings. The technology disclosed herein is not limited by the following embodiments.

A radio-frequency (RF) power supply system for a plasma processing apparatus includes an RF power supply that generates RF waves and a matcher for impedance matching with a chamber side. The matcher is used to set reflected waves of a power output from the RF power supply to be 0 W, in order to efficiently transmit RF waves to electrodes in a chamber. In addition, in the plasma processing apparatus, a plasma load impedance changes according to processing conditions. The matcher combines a coil and a capacitor to change an inductance and a capacitance such that the load impedance becomes 50 ohms, which is a characteristic impedance of the RF power supply. However, since a high voltage is applied to the matcher, sizes of the coil and the capacitor become large, and a size of the plasma processing apparatus itself becomes large. Therefore, in order to reduce the size of the plasma processing apparatus, it is expected to suppress reflected waves while omitting the matcher.

### [Configuration of Plasma Processing Apparatus 10]

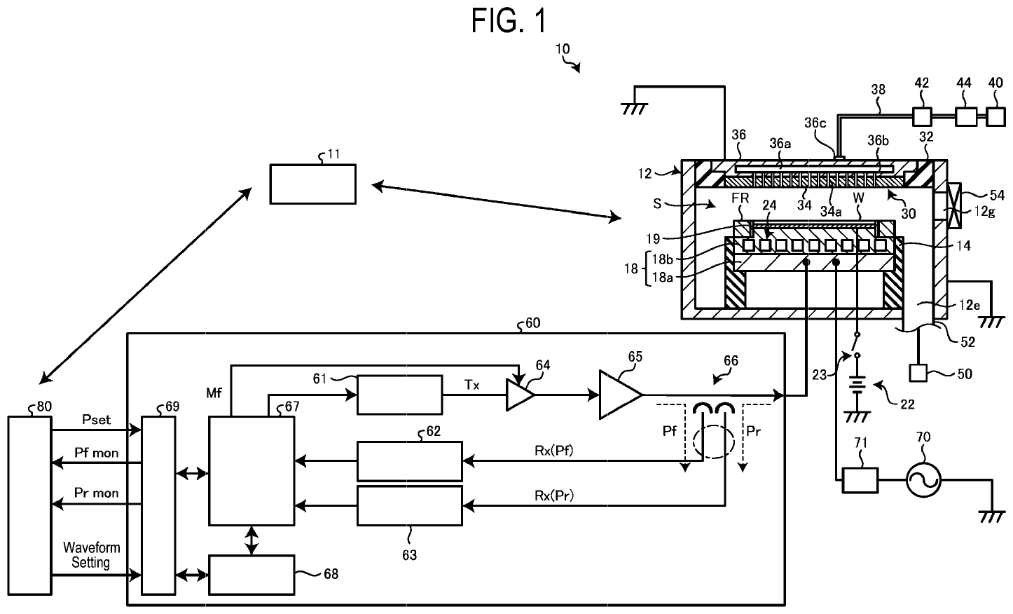

FIG. 1 is a view illustrating an example of a plasma processing apparatus according to an embodiment of the present disclosure. The plasma processing apparatus 10 illustrated in FIG. 1 is configured as a plasma processing apparatus using capacitively coupled plasma (CCP). The plasma processing apparatus 10 includes a controller 11 that controls the plasma processing apparatus 10 overall, and a substantially cylindrical processing container 12. An inner wall surface of the processing container 12 is made of, for example, anodized aluminum. The processing container 12 is securely grounded.

A substantially cylindrical support 14 is provided on a bottom of the processing container 12. The support 14 is made of, for example, an insulating material. The support 14 extends vertically from the bottom of the processing container 12 inside the processing container 12. A lower electrode 18 functioning as a stage for a wafer W is provided in the processing container 12. The lower electrode 18 is supported by the support 14.

The lower electrode 18 holds the wafer W as an object to be processed on a top surface thereof. The bottom electrode 18 includes a first plate 18a and a second plate 18b. The first plate 18a and the second plate 18b are made of a metal such as aluminum, and have a substantially disk shape. The second plate 18b is provided on the first plate 18a, and is electrically connected to the first plate 18a.

An electrostatic chuck 19 is provided on the second plate 18b of the lower electrode 18. The electrostatic chuck 19 has a structure in which an electrode, which is a conductive film, is interposed between a pair of insulating layers or insulating sheets. A DC power supply 22 is electrically connected to an electrode of the electrostatic chuck 19 via a switch 23. The electrostatic chuck 19 attracts the wafer W by an electrostatic force such as Coulomb force generated by a DC voltage from the DC power supply 22. Thus, it is possible for the electrostatic chuck 19 to hold the wafer W.

A focus ring FR is disposed on a peripheral edge of the second plate 18b of the lower electrode 18 to surround an edge of the wafer W and the electrostatic chuck 19. The focus ring FR is provided to improve etching uniformity. The focus ring FR may be made of a material appropriately selected according to a material of a film to be etched, and may be made of, for example, quartz.

A coolant channel 24 is provided inside the second plate 18b. The coolant channel 24 constitutes a temperature regulation mechanism. A heat transfer fluid, such as brine or gas, flows through the coolant channel 24. For example, a coolant supplied from a chiller unit provided outside the processing container 12 circulates in the coolant channel 24. By controlling a temperature of this coolant, a temperature of the wafer W supported by the electrostatic chuck 19 is controlled. In addition, the lower electrode 18 may include a heat transfer gas supply configured to supply a heat transfer gas to a gap between a rear surface of the wafer W and a top surface of the electrostatic chuck 19.

In addition, the plasma processing apparatus 10 includes an upper electrode 30. The upper electrode 30 is disposed above the lower electrode 18 to face the lower electrode 18. The lower electrode 18 and the upper electrode 30 are provided substantially parallel to each other. A processing space S where a plasma processing is performed on the wafer W is provided between the upper electrode 30 and the lower electrode 18.

The upper electrode 30 is supported in an upper portion of the processing container 12 via an insulative shield 32. In addition, the upper electrode 30 is connected to GND. The upper electrode 30 may include an electrode plate 34 and an electrode support 36. The electrode plate 34 faces the processing space S and is provided with a plurality of gas ejection holes 34a. The electrode plate 34 is made of, for example, silicon.

The electrode support 36 detachably supports the electrode plate 34, and may be made of, for example, a conductive material such as aluminum. This electrode support 36 may have a water cooling structure. Inside the electrode support 36, a gas diffusion chamber 36a is provided. A plurality of gas flow holes 36b in communication with the gas ejection holes 34a extend downward from the gas diffusion chamber 36a. In addition, the electrode support 36 is provided with a gas inlet 36c configured to guide a processing gas to the gas diffusion chamber 36a, and a gas supply pipe 38 is connected to the gas inlet 36c.

To the gas supply pipe 38, a gas source group 40 is connected via a valve group 42 and a flow rate controller group 44. The gas source group 40 includes a plurality of gas sources such as a fluorocarbon gas source, a rare gas source, and an oxygen (O₂) gas source. The fluorocarbon gas includes, for example, at least one of C₄F₆ gas or C₄F₈ gas. In addition, the rare gas includes at least one of various rare gases, such as Ar gas and He gas.

The valve group 42 includes a plurality of valves, and the flow rate controller group 44 includes a plurality of flow controllers such as mass flow controllers. The plurality of gas sources in the gas source group 40 are each connected to the gas supply pipe 38 via a corresponding valve in the valve group 42 and a corresponding flow controller in the flow rate controller group 44.

The processing container 12 is provided with an exhaust port 12e at a bottom thereof. An exhaust device 50 is connected to the exhaust port 12e via an exhaust pipe 52. The exhaust device 50 has a vacuum pump such as a turbomolecular pump, and is configured to depressurize a space inside the processing container 12 to a desired degree of vacuum. A load/unload port 12g for the wafer W is provided in a side wall of the processing container 12, and the load/unload port 12g is configured to be opened and closed by a gate valve 54.

The controller 11 includes a memory, a processor, and an input/output interface. The memory stores programs executed by the processor and recipes including conditions for respective processes. The processor executes the programs read from the memory and controls respective components of the plasma processing apparatus 10 via the input/output interface based on the recipes stored in the memory.

For example, the controller 11 controls respective components of the plasma processing apparatus 10 to perform a correction method, which will be described later. As a detailed example, the controller 11 executes a process of setting process conditions for respective components of the plasma processing apparatus 10 based on a recipe, such as a pressure (degree of vacuum) in the processing container 12, a type and flow rate of the processing gas, and the output of RF power. The controller 11 executes a process of preparing the wafer W to be processed by loading the wafer into the processing container 12. The controller 11 executes a process of initiating a processing according to the recipe. After starting the processing, the controller 11 controls a frequency-variable power supply 60 to calculate a traveling wave power Pf and a reflected wave power Pr and to execute correcting amplifier distortion and cancelling reflection.

In addition, as illustrated in FIG. 1, the plasma processing apparatus 10 includes the frequency-variable power supply 60, a RF power supply 70, and an upper-level controller 80.

The frequency-variable power supply 60 generates RF waves for plasma generation by using waveform data including set frequency components having a predetermined frequency range. The frequency-variable power supply 60 generates RF waves centered at 13.56 MHz by using, for example, waveform data including a set frequency component, which includes a signal component of 13.56 MHz as a set value and signal components of a plurality of arbitrary frequencies within a range of ±10% of the set value. Signals indicating a power setting Pset of the RF power, a waveform setting (waveform data) which is information such as a set frequency, and a control mode are input to the frequency-variable power supply 60 from the upper-level controller 80, which will be described later. The RF power output from the frequency-variable power supply 60 is supplied to the lower electrode 18. Alternatively, the RF power output from the frequency-variable power supply 60 may be supplied to the upper electrode 30.

The RF power supply 70 generates RF waves for drawing ions into the wafer W. The RF power supply 70 generates RF waves having a frequency lower than that of the RF waves generated by the frequency-variable power supply 60. The RF power supply 70 generates RF waves having, for example, a high frequency of 600 kHz. Hereinafter, in order to distinguish between the RF waves generated by the RF power supply 70 and the RF waves generated by the frequency-variable power supply 60, the RF waves generated by the RF power supply 70 will be referred to as “RF waves for bias.” The RF power supply 70 is connected to the lower electrode 18 via a matcher 71. The matcher 71 matches an output impedance of the RF power supply 70 and an input impedance on a load side (a side of the lower electrode 18). In addition, the RF power supply 70 and the matcher 71 used for RF power for bias may be a frequency-variable power supply 60′ prepared separately from the frequency-variable power supply 60.

The upper-level controller 80 is a controller that controls the frequency-variable power supply 60 in response to instructions from the controller 11. The upper-level controller 80 outputs the power setting Pset, the control mode, and the waveform setting of the RF power to the frequency-variable power supply 60 according to a recipe input from the controller 11. The waveform setting is, for example, waveform data for setting a center frequency, a waveform shape, and the like of the RF waves. In addition, monitor values Pfmon and Prmon, which will be described later, are input from the frequency-variable power supply 60 to the upper-level controller 80. The upper-level controller 80 outputs the input monitor values Pfmon and Prmon to the controller 11. In addition, the upper-level controller 80 may be included in the controller 11.

The frequency-variable power supply 60 include a modulator 61, demodulators 62 and 63, a preamplifier 64, an amplifier 65, a directional coupler 66, the operation part 67, a storage 68, and an input/output part 69.

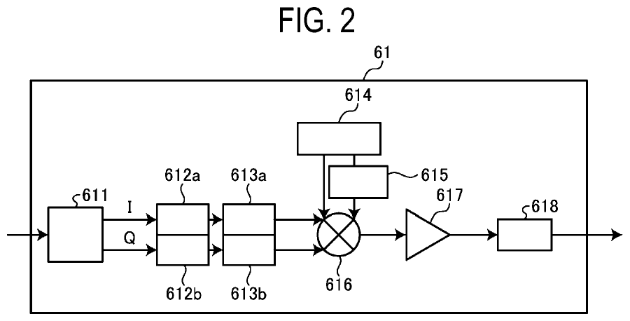

The modulator 61 generates a modulated RF signal based on corrected waveform data input from the operation part 67. Here, the modulator 61 will be described with reference to FIG. 2. FIG. 2 is a block diagram illustrating an example of a functional configuration of the modulator according to the present embodiment. As illustrated in FIG. 2, the modulator 61 includes an inverse Fourier transformer 611, digital/analog (D/A) converters 612a and 612b, low pass filters (LPFs) 613a and 613b, a phase-locked loop (PLL) oscillator 614, a phase shifter 615, a multiplier 616, an amplifier 617, and a band pass filter (BPF) 618.

The inverse Fourier transformer 611 separates in-phase component data (I data) and quadrature component data (Q data) of the waveform data by inverse-Fourier-transforming the corrected waveform data input from the operation part 67. The I data and Q data of the waveform data separated by the inverse Fourier transformer 611 are D/A-converted by the D/A converters 612a and 612b and are input to the multiplier 616 via the LPFs 613a and 613b.

The PLL oscillator 614 generates a reference carrier wave and outputs the generated reference carrier wave to the phase shifter 615 and the multiplier 616. The phase shifter 615 shifts a phase of the reference carrier input from PLL oscillator 614 by 90 degrees and outputs the phase-shifted reference carrier to the multiplier 616. The multiplier 616 multiplies the I data input from the LPF 613a by the reference carrier input from the PLL oscillator 614. The multiplier 616 multiplies the Q data input from the LPF 613b by the reference carrier input from the phase shifter 615. Each multiplication result of the multiplier 616 is synthesized by an adder (not illustrated) and is generated as RF waves for plasma generation. The generated RF waves are amplified by the amplifier 617 and are output to the preamplifier 64 via the BPF 618.

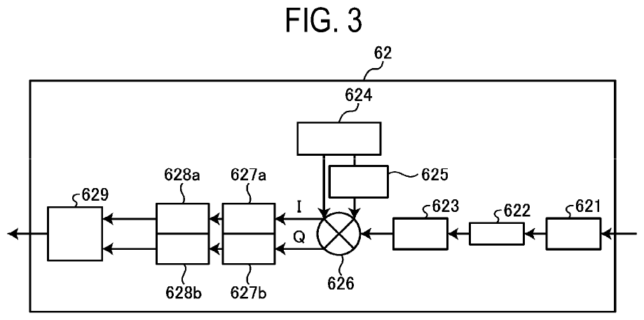

The demodulators 62 and 63 demodulate the traveling wave power Pf and the reflected wave power Pr, each of which is input from the directional coupler 66, and provide the waveform data of the demodulated traveling wave power Pf and reflected wave power Pr to the operation part 67. The demodulator 62 is an example of a first demodulator, and the demodulator 63 is an example of a second demodulator. Here, the demodulators 62 and 63 will be described with reference to FIG. 3. FIG. 3 is a block diagram illustrating an example of a functional configuration of the demodulators according to the present embodiment. Since the demodulator 62 and the demodulator 63 have the same configuration, the demodulator 62 will be described with reference to FIG. 3.

As illustrated in FIG. 3, the demodulator 62 includes an attenuator (ATT) 621, an RF switch 622, a BPF 623, a PLL oscillator 624, a phase shifter 625, a multiplier 626, LPFs 627a and 627b, analog/digital (A/D) converters 628a and 628b and a Fourier transformer 629.

The ATT 621 attenuates the traveling wave power Pf input from the directional coupler 66, that is, extracted RF power for plasma generation toward the lower electrode 18, to be a predetermined level. The RF switch 622 switches on/off of the traveling wave power Pf to a side of a rear stage. The RF switch 622 is turned off when an input signal of a predetermined voltage or higher is input to the A/D converters 628a and 628b to avoid a failure due to overvoltage. The traveling wave power Pf attenuated by ATT 621 is input to the multiplier 626 via the RF switch 622 and the BPF 623.

The PLL oscillator 624 generates a reference carrier wave and outputs the generated reference carrier wave to the phase shifter 625 and the multiplier 626. The phase shifter 625 shifts a phase of the reference carrier input from the PLL oscillator 624 by 90 degrees and outputs the phase-shifted reference carrier to the multiplier 626. The multiplier 626 multiplies the traveling wave power Pf input from BPF 623 by the reference carrier wave input from the PLL oscillator 624. The multiplier 626 multiplies the traveling wave power Pf input from BPF 623 by the reference carrier wave input from the phase shifter 625. The multiplier 626 outputs the I data of the multiplication result to the A/D converter 628a via the LPF 627a. The multiplier 626 outputs the Q data of the multiplication result to the A/D converter 628b via the LPF 627b. The I data and Q data are A/D-converted by the A/D converters 628a and 628b, and the A/D-converted I data and Q data are input to Fourier transformer 629.

The Fourier transformer 629 Fourier-transforms the A/D-converted I data and Q data, and calculates waveform data (amplitude: |Rx(Pf)|, phase: θ(Pf)) in a predetermined frequency range. The demodulator 63 calculates waveform data (amplitude: |Rx(Pr)|, phase: θ(Pr)). The Fourier transformer 629 outputs the calculated waveform data to the operation part 67.

Returning to the description of FIG. 1, the preamplifier 64 is an amplifier configured to change an amplification factor at a frequency and a power set value in response to a power command value Mf input from the operation part 67. In addition, the power command value Mf is an example of a power correction value. The preamplifier 64 amplifies the RF waves input from the modulator 61 with the amplification factor corresponding to the power command value Mf and outputs the amplified RF waves to the amplifier 65.

The amplifier 65 amplifies the RF waves input from the preamplifier 64 to a predetermined power. The amplifier 65 outputs the amplified RF waves to the lower electrode 18 as RF power for plasma generation via the directional coupler 66.

The directional coupler 66 is provided in a transmission path between the amplifier 65 and the lower electrode 18, and extracts the traveling wave power Pf and the reflected wave power Pr. The extracted traveling wave power Rx(Pf) is input to the demodulator 62. In addition, the extracted reflected wave power Rx(Pr) is input to the demodulator 63. In the following description, the traveling wave power Rx(Pf) may be simply referred to as traveling wave power Pf, and the reflected wave power Rx(Pr) may be simply referred to as reflected wave power Pr.

The operation part 67 calculates correction values according to a plurality of frequencies within a frequency range that can be output from the frequency-variable power supply 60. The power setting Pset of RF power, the waveform setting (waveform data) which is information such as the set frequency and the like, and the control mode are input to the operation part 67 via the input/output part 69 from the upper-level controller 80. The operation part 67 executes a process of calculating the traveling wave power Pf, a process of calculating the reflected wave power Pr, a process of setting the power command value Mf, a process of correcting amplifier distortion, and a process of cancelling reflection. The operation part 67 outputs the corrected waveform data, which has undergone the amplifier distortion correction process and the reflection cancellation process, to the modulator 61 and outputs the power command value Mf to the preamplifier 64. In addition, the operation part 67 outputs the monitor value Pfmon of the traveling wave power Pf and the monitor value Prmon of the reflected wave power Pr to the upper-level controller 80.

The storage 68 stores information used in respective processes in the operation part 67. The storage 68 stores various information such as a Pf component and a Pf phase component of the traveling wave power Pf, a Pr component and a Pr phase component of the reflected wave power Pr, a Pf conversion value k1, and a Pr conversion value k3, which will be described later.

### [Calibration]

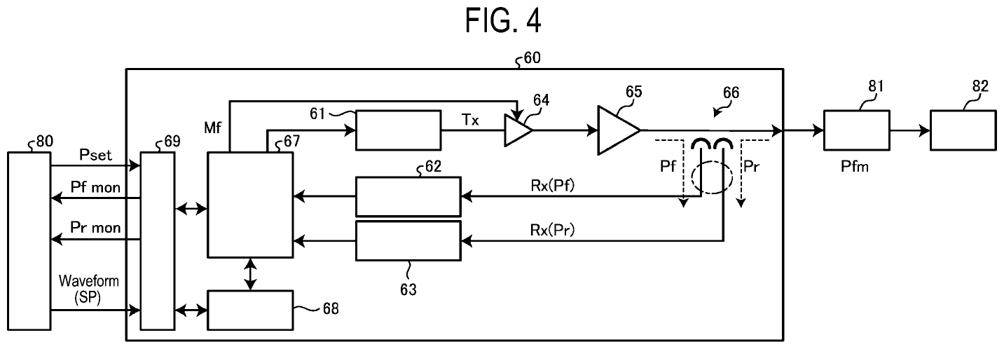

Next, calibration of the frequency-variable power supply 60 will be described with reference to FIGS. 4 to 13. FIG. 4 is a block diagram illustrating an example of connections when acquiring the power command value Mf and the Pf conversion value k1. As illustrated in FIG. 4, when acquiring the power command value Mf and the Pf conversion value k1, a dummy load 82 is connected to an output of the frequency-variable power supply 60 via a power meter 81. Subsequently, the upper-level controller 80 outputs a single peak (SP) waveform of a frequency F as the power setting Pset to the frequency-variable power supply 60. Since the dummy load 82 is connected to the output of the frequency-variable power supply 60, no reflection is generated. At this time, a measurement value Pfm of the power meter 81 may be regarded as RF power actually output from the frequency-variable power supply 60. In addition, from the directional coupler 66, the traveling wave power Rx(Pf) extracted from the traveling wave power Pf flows toward the demodulator 62. In addition, the reflected wave power Pr flowing toward the demodulator 63 becomes zero.

When acquiring the power command value Mf and the Pf conversion value k1, measurement values Pfm at power settings Pset(0) to Pset(n) are measured, with respect to a predetermined frequency range F(1) to F(m). Here, the frequency F(1) is a lower limit value of the predetermined frequency range, and the frequency F(m) is an upper limit value of the predetermined frequency range. The power setting Pset(0) is a minimum settable value (0 W) of the RF power, and the power setting Pset(n) is a maximum settable value of the RF power. As the power command value Mf, a power command value Mf(k, h) when the measurement value Pfm matches with each power setting Pset(k) within the range of power settings Pset(0) to Pset(n) for each frequency F(h) within the range of frequencies F(1) to F(m) is obtained. That is, the power command value Mf(k, h) is a power correction value that satisfies a relationship of (power setting Pset(k))=(measurement value Pfm(k, h)).

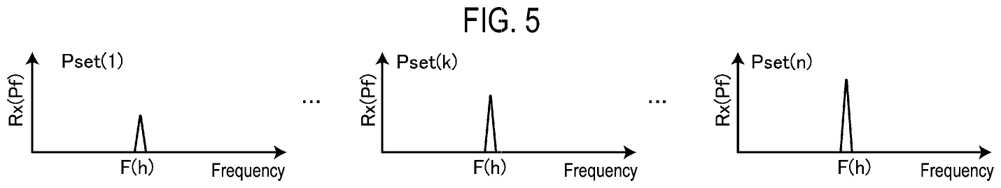

FIG. 5 is a view illustrating examples of single-peak waveforms of the traveling wave power. The single-peak waveforms illustrated in FIG. 5 are waveforms of the traveling wave power Rx(Pf) extracted at the frequency F(h) and are represented by the power settings Pset(1) to Pset(n). Since the power setting Pset(0) is 0 W, the waveform thereof is omitted without being illustrated.

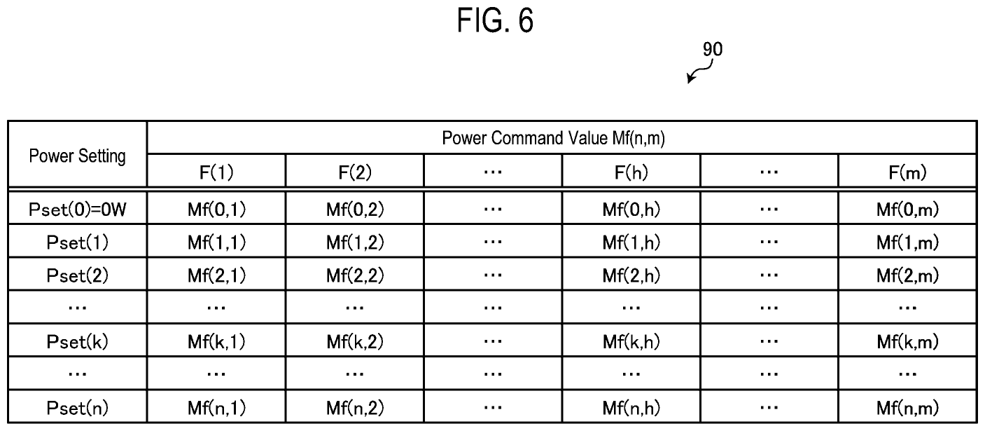

FIG. 6 is a view illustrating an example of a relationship between the power setting Pset and the power command value Mf at each frequency. Table 90 illustrated in FIG. 6 summarizes the power command values Mf(n, m) obtained with respect to the predetermined frequency range F(1) to F(m) and the range of the power settings Pset(0) to Pset(n). Table 90 obtained in calibration is stored in the storage 68.

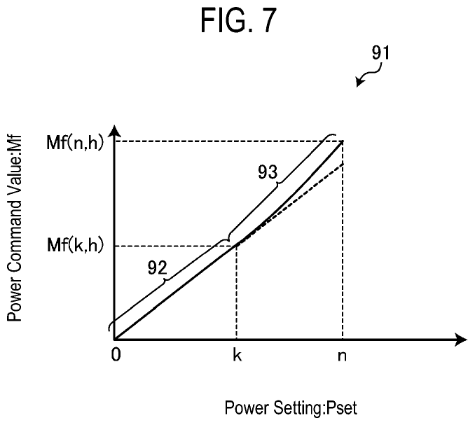

FIG. 7 is a graph illustrating an example of a relationship between the power setting Pset and the power command value Mf at a specific frequency. As illustrated in the graph 91 of FIG. 7, when the power setting Pset and the power command value Mf are illustrated in a graph, the graph is divided into a section 92 of the power settings Pset(0) to Pset(k), which is a linear region of the amplifiers (the preamplifier 64 and amplifier 65), and a section 93 of the power settings Pset(k+1) to Pset(n), which is a non-linear region. In the section 92, (power command value Mf)/(power setting Pset) is a constant value. That is, in the linear region of the amplifier, (power command value Mf)/(power setting Pset) may be set to a fixed value. On the other hand, in the non-linear region of the amplifiers, Table 90 is used to refer to the power command value Mf corresponding to the power setting Pset. In addition, when the amplifiers do not depend on the frequency and power, (power command value Mf)/(power setting Pset) may be set to a constant value. In addition, since data in Table 90 is discrete, an intermediate value is obtained by proportionally dividing the preceding and succeeding power command values Mf.

Regarding the Pf conversion value k1, first, the waveform data of traveling wave power (amplitude: |Rx(Pf(h))|, phase: φ(Pf(h)) for each power setting Pset(k) is obtained for each frequency F(h). Next, a Pf conversion value k1(k, h) when |Rx(Pf(h))| matches with the measurement value Pfm is obtained. That is, when (power setting Pset(k))=(measurement value Pfm(k, h))=(traveling wave power Pf(k, h)), the Pf conversion value k1(k, h) is a correction value of a reception system on a side of the demodulator 62 where a relationship of (measurement value Pfm(k, h))=(traveling wave power Pf(k, h))=(Pf conversion value k1(k,h)×|Rx(Pf(h))|) is satisfied.

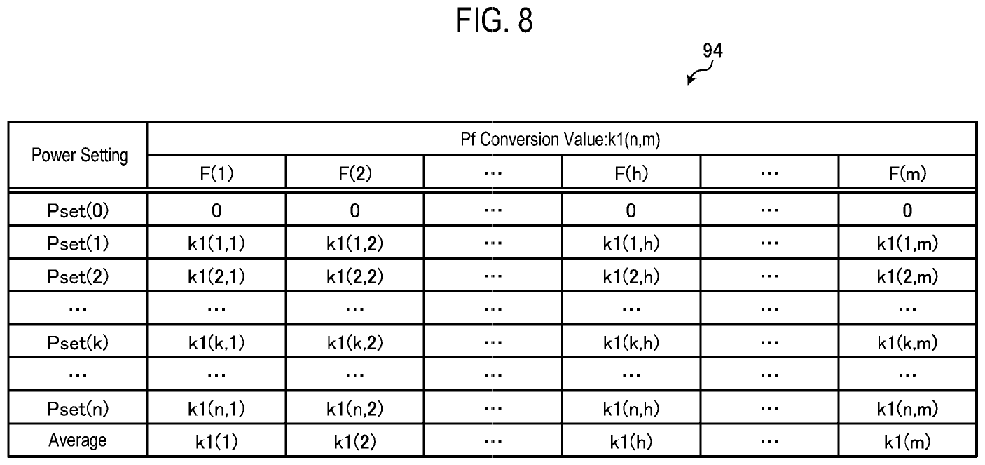

FIG. 8 is a view illustrating an example of a relationship between the power setting Pset and the Pf conversion value k1 at each frequency. Table 94 illustrated in FIG. 8 summarizes Pf conversion values k1(n, m) obtained with respect to the predetermined frequency range F(1) to F(m) and the range of power settings Pset(0) to Pset(n). Table 94 obtained in calibration is stored in the storage 68.

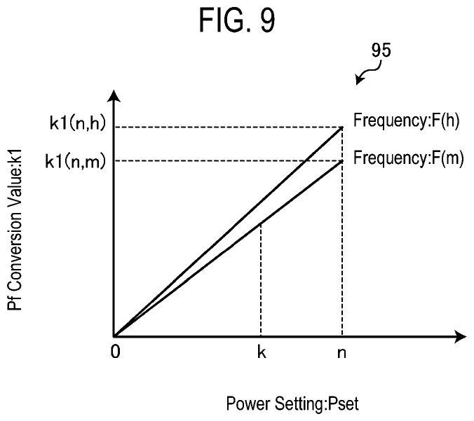

FIG. 9 is a view illustrating an example of frequency characteristics of the relationship between the power setting Pset and the Pf conversion value k1. As illustrated in the graph 95 of FIG. 9, when the power setting Pset and the Pf conversion value k1 are illustrated in a graph, the graph has a linear relationship when the frequency F is constant, but a slope of the graph changes when the frequency F changes. That is, in the directional coupler 66, a degree of coupling with respect to power is constant, and a degree of coupling with respect to frequency changes. For this reason, the Pf conversion value k1 may be set to be a fixed value by using an average value, and in this case, a relationship of (traveling wave power Pf(h) at the frequency F(h))=(Pf conversion value k1(h)×|Rx(Pf(h))|) may be established. As in Table 90, since data in Table 94 is discrete, an intermediate value is obtained by proportionally dividing the preceding and succeeding Pf conversion values k1.

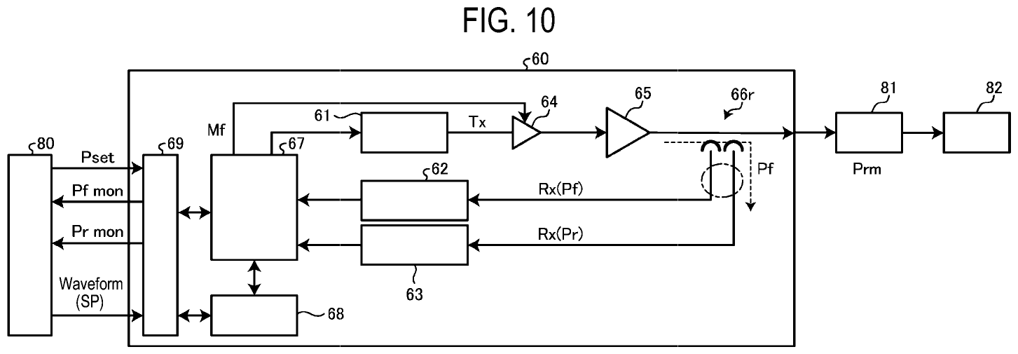

FIG. 10 is a block diagram illustrating an example of connections when acquiring the Pr conversion value k3. As illustrated in FIG. 10, when acquiring the Pr conversion value k3, a direction of the directional coupler 66 in the frequency-variable power supply 60 is reversed and connected as a directional coupler 66r, and a dummy load 82 is connected to the output of the frequency-variable power supply 60 via the power meter 81. Next, the upper-level controller 80 outputs a single peak (SP) waveform having a frequency F as the power setting Pset to the frequency-variable power supply 60. Since the dummy load 82 is connected to the output of the frequency-variable power supply 60, no reflection is generated. At this time, a measurement value Prm of the power meter 81 may be regarded as the RF power actually output from the frequency-variable power supply 60. In addition, from the directional coupler 66r, the traveling wave power Rx(Pf) extracted from the traveling wave power Pf flows toward the demodulator 63 as reflected wave power Rx(Pr). In addition, the reflected wave power Pr flowing toward the demodulator 62 as the traveling wave power Rx(Pf) becomes zero.

As in the case of acquiring the Pf conversion value k1, when acquiring the Pr conversion value k3, measurement values Prm at power settings Pset(0) to Pset(n) are measured with respect to the predetermined frequency range F(1) to F(m). Regarding the Pr conversion value k3, first, waveform data of reflected wave power (amplitude: |Rx(Pr(h))|, phase: φ(Pr(h)) for each power setting Pset(k) is obtained for each frequency F(h). Next, the Pr conversion value k3(k, h) when |Rx(Pr(h))| matches with the measurement value Prm is obtained. Here, when acquiring the Pr conversion value k3, since the reversed directional coupler 66r is used, (power setting Pset(k))≠(measurement value Prm(k, h))=(reflected wave power Pr(k, h)). That is, the Pr conversion value k3 (k, h) is a correction value of a reception system on a side of the demodulator 63 where a relationship of (measured value Prm(k, h))=(reflected wave power Pr(k, h))=(Pr conversion value k3(k, h)×|Rx(Pr(h))|) is satisfied.

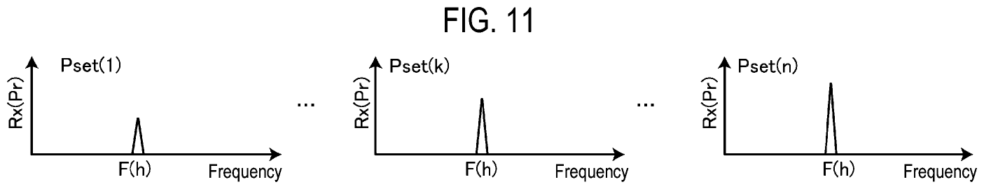

FIG. 11 is a view illustrating examples of single-peak waveforms of the reflected wave power. The single-peak waveforms illustrated in FIG. 11 are waveforms of the reflected wave power Rx(Pr) extracted at the frequency F(h) and are represented by power settings Pset(1) to Pset(n). Since the power setting Pset(0) is 0 W, the waveform thereof is omitted without being illustrated. In addition, since the reversed directional coupler 66r is used when acquiring the Pr conversion value k3, the waveforms are the same as those in the case of the traveling wave power illustrated in FIG. 5.

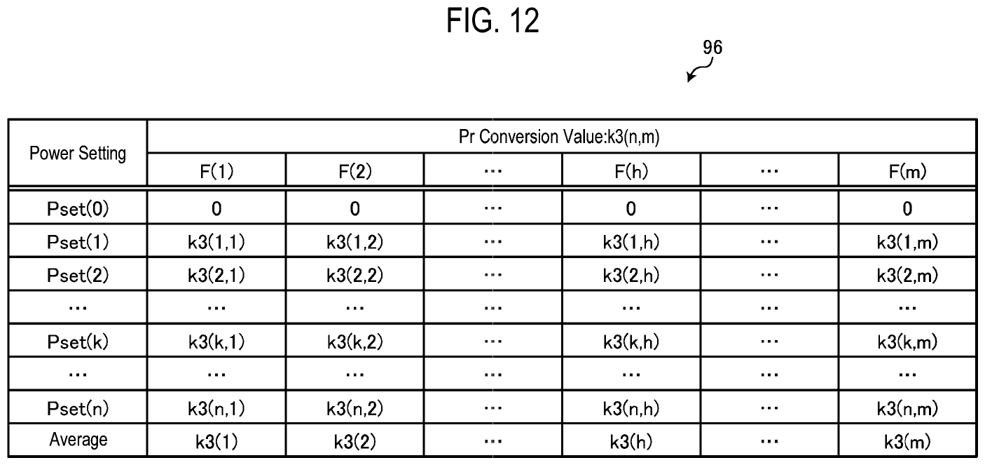

FIG. 12 is a view illustrating an example of a relationship between the power setting Pset and the Pr conversion value k3 at each frequency. Table 96 illustrated in FIG. 12 summarizes Pr conversion values k3(n, m) obtained with respect to the predetermined frequency range F(1) to F(m) and the range of power settings Pset(0) to Pset(n). Table 96 obtained in calibration is stored in the storage 68.

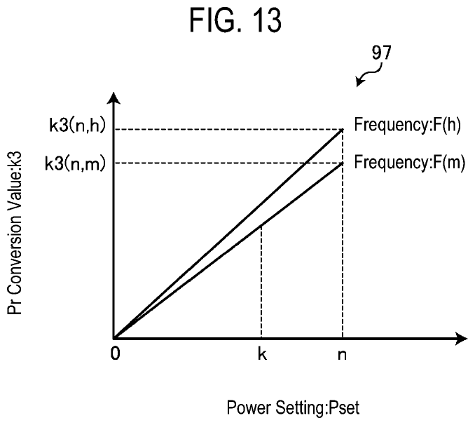

FIG. 13 is a view illustrating an example of frequency characteristics of the relationship between the power setting Pset and the Pr conversion value k3. As illustrated in the graph 97 of FIG. 13, when the power setting Pset and the Pr conversion value k3 are illustrated in a graph, the graph has a linear relationship when the frequency F is constant, but a slope of the graph changes when the frequency F changes. That is, in the directional coupler 66r, a degree of coupling with respect to power is constant, and a degree of coupling with respect to frequency changes. For this reason, the Pr conversion value k3 may be set to be a fixed value by using an average value, and in this case, a relationship of (reflected wave power Pr(h) at the frequency F(h))=(Pr conversion value k3(h)×|Rx(Pr(h))|) may be established. As in Table 94, since data in Table 96 is discrete, an intermediate value is obtained by proportionally dividing the preceding and succeeding Pr conversion values k3.

### [Details of Operation Part 67]

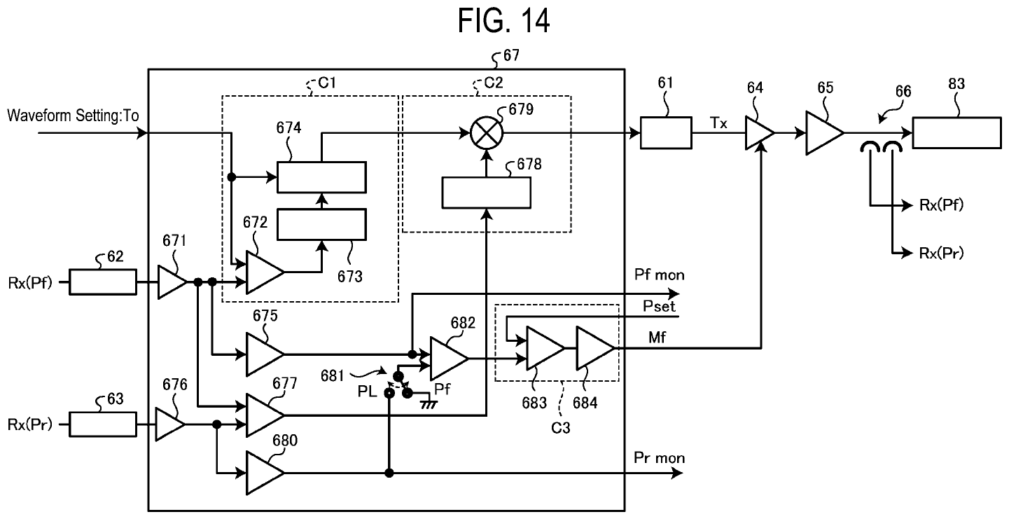

Next, the operation part 67 will be described with reference to FIG. 14. FIG. 14 is a block diagram illustrating an example of a functional configuration from an operation part to a plasma load 83 according to the present embodiment. As illustrates in FIG. 14, the operation part 67 includes operators 671 and 676, comparators 672 and 677, a first correction value generator 673, a waveform generator 674, integrators 675 and 680, a second correction value generator 678, a synthesizer 679, a switcher 681, a subtractor 682, a comparator 683, and an operator 684. In addition, the comparator 672, the first correction value generator 673, and the waveform generator 674 constitute a first corrector C1 that corrects amplifier distortion. The second correction value generator 678 and the synthesizer 679 constitute a second corrector C2 that cancels reflection. The comparator 683 and the operator 684 constitute a third corrector C3 that corrects power. That is, the first corrector C1 performs a process of correcting amplifier distortion by predistortion. The second corrector C2 performs a process of cancelling reflection. The third corrector C3 performs a process of controlling input power to a load to be constant or a process of controlling effective power to be constant.

When the waveform data of the traveling wave power Pf (amplitude: |Rx(Pf)|, phase: θ(Pf)) is input from the demodulator 62, the operator 671 corrects the waveform data with reference to the Pf conversion value k1 stored in the storage 68. When the waveform data has a plurality of frequencies (1 to m) within a predetermined frequency range, the operator 671 corrects Pf (amplitude) components by using (traveling wave power Pf(h))=(Pf conversion value k1(h)×|Rx(Pf(h))|) where h=1 to m. The k1-corrected waveform data (|Pf(h)|, θ(Pf(h)) is output to the comparators 672 and 677 and the integrator 675.

The waveform data To for waveform setting and the k1-corrected waveform data are input to the comparator 672. When the waveform data To for waveform setting has a plurality of frequencies (1 to m) within a predetermined frequency range, the waveform data To for waveform setting has an amplitude represented by |To(h)| and a phase represented by θ(To(h)) where h=1 to m. Based on the amplitude components and the phase components of the input waveform, the comparator 672 compares and calculates an amplification factor and an amplification phase difference by using the following Equations (1) and (2). The comparator 672 outputs the amplification factor and the amplification phase difference as a calculation result to the first correction value generator 673.

Amplification factor: G(h)=|Pf(h)|/|To(h)| (1)

Amplification phase difference: θ(h)=θ(Pf(h))−θ(To(h)) (2)

When the amplification factor and the amplification phase difference are input from the comparator 672, the first correction value generator 673 generates an amplifier distortion correction value for correcting amplifier distortion based on the amplification factor and the amplification phase difference. For example, when amplification factors at frequencies Fₐ, F_{b}, and F_{c} are Go, Go-δb, and Go-δc, respectively, with respect to a reference amplification factor Go, the first correction value generator 673 generates 1, 1+δb/Go, and 1+δc/Go as linear correction values among the amplifier distortion correction values. Similarly, for example, when the phases at frequencies Fₐ, F_{b}, and F_{c} are φo, φo−δθb, and φo−δθc, respectively, with respect to a reference phase difference φo, the first correction value generator 673 generates φo, φo+δθb, and φo+δθc as phase correction values among the amplifier distortion correction values. The first correction value generator 673 outputs the generated amplifier distortion correction values to the waveform generator 674.

The waveform generator 674 generates waveform data after amplifier distortion correction, based on the waveform data To for waveform setting and the amplifier distortion correction values input from the first correction value generator 673. The waveform generator 674 outputs the generated waveform data after amplifier distortion correction to the synthesizer 679.

When the k1-corrected waveform data is input from the operator 671, the integrator 675 integrates |Pf(1)| to |Pf(m)| as the Pf components of the k1-corrected waveform data to generate a monitor value Pfmon. The integrator 675 outputs the generated monitor value Pfmon to the subtractor 682 and the upper-level controller 80.

When the waveform data of the reflected wave power Pr (amplitude: |Rx(Pr)|, phase: θ(Pr)) is input from the demodulator 63, the operator 676 corrects the waveform data with reference to the Pr conversion value k3 stored in the storage 68. When the waveform data has a plurality of frequencies (1 to m) within a predetermined frequency range, the operator 676 corrects Pr (amplitude) components by using (reflected wave power Pr(h))=(Pr conversion value k3(h)×|Rx(Pr(h))|) where h=1 to m. The k3-corrected waveform data (|Pr(h)|, θ(Pr(h)) is output to the comparator 677 and the integrator 680.

The k1-corrected waveform data and the k3-corrected waveform data are input to the comparator 677. Based on the amplitude components and the phase components of the input waveform, the comparator 677 compares and calculates a reflectance and a reflection phase difference by using the following Equations (3) and (4). The comparator 677 outputs the reflectance and the reflection phase difference as a calculation result to the second correction value generator 678.

Reflectance: R(h)=|Pr(h)|/|Pf(h)| (3)

Reflection phase difference: θ(h)=θ(Pr(h)−θ(Pf(h)) (4)

When the reflectance and the reflection phase difference are input from the comparator 677, the second correction value generator 678 generates a reflection correction value that cancels the reflection based on the reflectance and the reflection phase difference. The second correction value generator 678 generates, for example, reflection correction values corresponding to the reflectances at frequencies Fₐ, F_{b}, and F_{c}, and reflection phase correction values having a phase difference of +180 degrees from the reflection phase differences. That is, the second correction value generator 678 generates, as the reflection correction values, a waveform having an opposite phase that cancels the reflectances and the reflection phase differences. The second correction value generator 678 outputs the generated reflection correction values to the synthesizer 679.

The synthesizer 679 synthesizes the reflection correction values, which are input from the second correction value generator 678, with the waveform data after amplifier distortion correction, which is input from the waveform generator 674. The synthesizer 679 outputs the synthesized waveform data after reflection correction to the modulator 61.

When the k3-corrected waveform data is input from the operator 676, the integrator 680 integrates |Pr(1)| to |Pr(m)| as the Pr components of the k3-corrected waveform data to generate a monitor value Prmon. The integrator 680 outputs the generated monitor value Prmon to the switcher 681 and the upper-level controller 80.

The switcher 681 switches one of the inputs to the subtractor 682 between the monitor value Prmon and ground potential (0 V). Based on the control mode input from the upper-level controller 80, the switcher 681 switches, as the power command value Mf, between using a Pf mode that controls the traveling wave power Pf (input power) to be constant and using a PL mode that controls the effective power (load power) to be constant. The switcher 681 outputs the ground potential to the subtractor 682 when the Pf mode is selected. On the other hand, the switcher 681 outputs the monitor value Prmon to the subtractor 682 when the PL mode is selected.

To the subtractor 682, the monitor value Pfmon is input from the integrator 675 and the ground potential or the monitor value Prmon is input from the switcher 681. The subtractor 682 outputs the monitor value Pfmon to the comparator 683 when the ground potential is input from the switcher 681. On the other hand, when the monitor value Prmon is input from the switcher 681, the subtractor 682 outputs a difference value obtained by subtracting the monitor value Prmon from the monitor value Pfmon to the comparator 683.

To the comparator 683, the power setting Pset, which is a set value of RF power, is input from the upper-level controller 80 and the monitor value Pfmon or the difference value is input from the subtractor 682. When the monitor value Pfmon is input from the subtractor 682, the comparator 683 outputs a comparison result between the power setting Pset and the monitor value Pfmon to the operator 684. On the other hand, when the difference value is input from the subtractor 682, the comparator 683 outputs a comparison result between the power setting Pset and the difference value to the operator 684.

When the comparison result between the power setting Pset and the monitor value Pfmon is input from the comparator 683, the operator 684 calculates the power command value Mf that satisfies (power setting Pset)=(monitor value Pfmon). On the other hand, when the comparison result between the power setting Pset and the difference value is input from the comparator 683, the operator 684 calculates the power command value Mf obtained by adding the difference value to the power setting Pset. The operator 684 outputs the calculated power command value Mf to the preamplifier 64.

The preamplifier 64 amplifies the RF waves, which are modulated by the modulator 61 based on the waveform data after reflection correction, with the amplification factor corresponding to the power command value Mf, and outputs the amplified RF waves to the amplifier 65. The RF power amplified by the amplifier 65 is output to the lower electrode 18 and supplied to the plasma load 83, and the directional coupler 66 extracts the traveling wave power Rx (Pf) and the reflected wave power Rx (Pr). The extracted travelling wave power Rx(Pf) and reflected wave power Rx(Pr) are input and fed back to the demodulators 62 and 63.

### [Calibration Method]

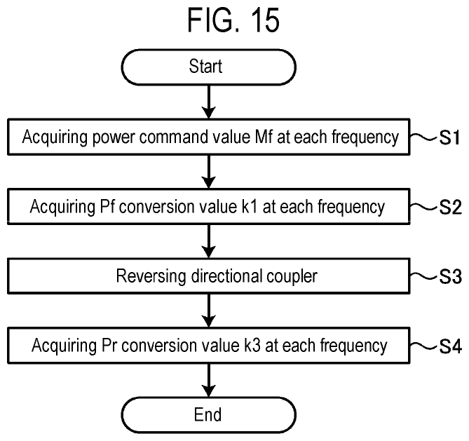

Next, a calibration method according to the present embodiment will be described. FIG. 15 is a flowchart illustrating an example of a calibration process in the present embodiment.

The calibration method according to the present embodiment is executed in advance before a processing in the plasma processing apparatus 10 is performed. In addition, the calibration method may be executed in advance by a singleton of the frequency-variable power supply 60. The following calibration method will be described as being controlled and executed by the upper-level controller 80.

First, setting is made such that the dummy load 82 is connected to the output of the frequency-variable power supply 60 via the power meter 81. The upper-level controller 80 sets the frequency-variable power supply 60 to output RF power with the power settings Pset(0) to Pset(n) within the predetermined frequency range F(1) to F(m). The upper-level controller 80 controls the frequency-variable power supply 60 to acquire the power command value Mf at each of the frequencies F(1) to F(m) and the power settings Pset(0) to Pset(n) (step S1). The acquired power command value Mf is stored in the storage 68 of the frequency-variable power supply 60.

The upper-level controller 80 sets the frequency-variable power supply 60 to output RF power with the power settings Pset(0) to Pset(n) within the predetermined frequency range F(1) to F(m). The upper-level controller 80 controls the frequency-variable power supply 60 to acquire the Pf conversion value k1 at each of the frequencies F(1) to F(m) and the power settings Pset(0) to Pset(n) (step S2). The acquired Pf conversion value k1 is stored in the storage 68 of the frequency-variable power supply 60.

Subsequently, setting is changed such that the direction of the directional coupler 66 in the frequency-variable power supply 60 is reversed and is connected as a directional coupler 66r (step S3). The upper-level controller 80 sets the frequency-variable power supply 60 to output RF power with the power settings Pset(0) to Pset(n) within the predetermined frequency range F(1) to F(m). The upper-level controller 80 controls the frequency-variable power supply 60 to acquire the Pr conversion value k3 at each of the frequencies F(1) to F(m) and the power settings Pset(0) to Pset(n) (step S4). The acquired Pr conversion value k3 is stored in the storage 68 of the frequency-variable power supply 60. Thus, it is possible for the frequency-variable power supply 60 to complete calibration of the power command value Mf, the Pf conversion value k1, and the Pr conversion value k3.

### [Correction Method]

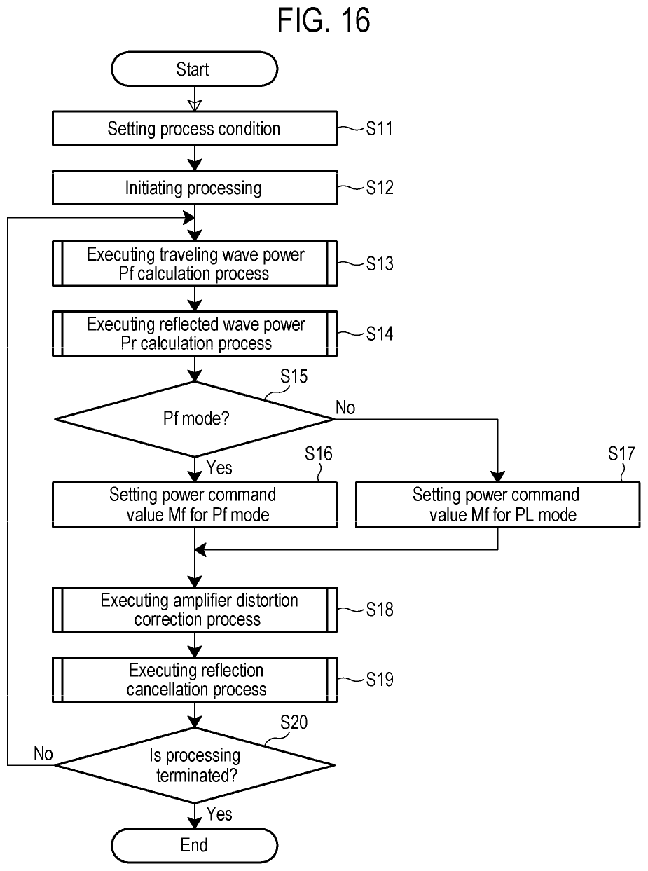

Next, a correction method according to the present embodiment will be described. FIG. 16 is a flowchart illustrating an example of a correction process in the present embodiment.

The controller 11 of the plasma processing apparatus 10 executes a process of setting process conditions for respective components of the plasma processing apparatus 10 based on a recipe, such as the pressure inside the processing container 12, the type and flow rate of a processing gas, the output of RF power (step S11).

The controller 11 executes a process of loading the wafer W to be processed into the processing container 12 to prepare the wafer W. The controller 11 executes a process of initiating a processing according to the recipe (step S12). At this time, the frequency-variable power supply 60 initiates outputting RF power with waveform data (an initial value) according to the recipe. After initiating the processing, the controller 11 controls the frequency-variable power supply 60 to execute an RF power correction process.

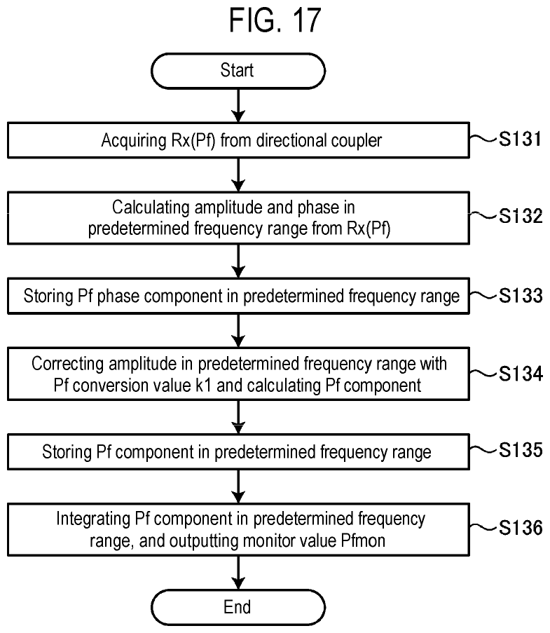

The frequency-variable power supply 60 executes a traveling wave power Pf calculation process (step S13). Here, the traveling wave power Pf calculation process will be described with reference to FIG. 17. FIG. 17 is a flowchart illustrating an example of the traveling wave power Pf calculation process.

The demodulator 62 acquires the traveling wave power Rx(Pf) from the directional coupler 66 (step S131). The demodulator 62 demodulates the traveling wave power Rx(Pf) and calculates an amplitude and phase (waveform data) in a predetermined frequency range (step S132). The demodulator 62 outputs the calculated waveform data to the operation part 67.

When the waveform data is input from the demodulator 62, the operation part 67 stores the Pf phase component of the waveform data in the predetermined frequency range in the storage 68 (step S133). The operation part 67 reads the Pf conversion value k1 from the storage 68, corrects the amplitude in the predetermined frequency range in the waveform data with the Pf conversion value k1, and calculates the Pf component (step S134). The operation part 67 stores the calculated Pf component in the predetermined frequency range in the storage 68 (step S135). In addition, the operation part 67 integrates the Pf component in the predetermined frequency range and outputs the monitor value Pfmon to the upper-level controller 80 (step S136).

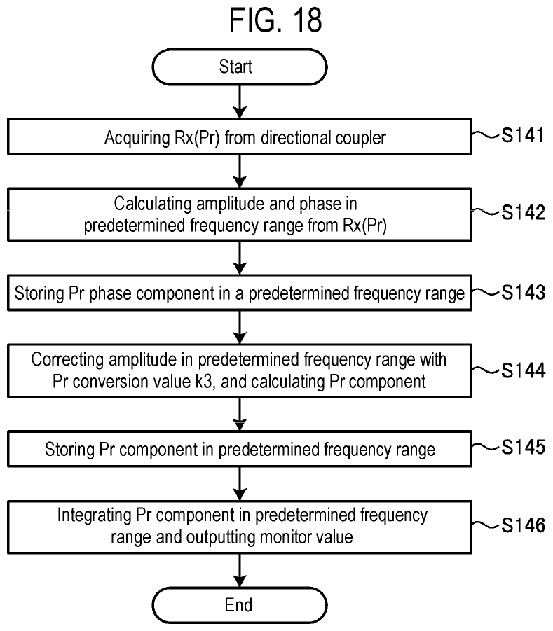

Returning to the description of FIG. 16, the frequency-variable power supply 60 executes a calculation process of the reflected wave power Pr (step S14). Here, the calculation process of the reflected wave power Pr will be described with reference to FIG. 18. FIG. 18 is a flow chart illustrating an example of the calculation process of the reflected wave power Pr.

The demodulator 63 acquires the reflected wave power Rx(Pr) from the directional coupler 66 (step S141). The demodulator 63 demodulates the reflected wave power Rx(Pr) and calculates an amplitude and phase (waveform data) in a predetermined frequency range (step S142). The demodulator 63 outputs the calculated waveform data to the operation part 67.

When the waveform data is input from the demodulator 63, the operation part 67 stores the Pr phase component of the waveform data in the predetermined frequency range in the storage 68 (step S143). The operation part 67 reads the Pr conversion value k3 from the storage 68, corrects the amplitude in the predetermined frequency range in the waveform data with the Pr conversion value k3, and calculates the Pr component (step S144). The operation part 67 stores the calculated Pr component in the predetermined frequency range in the storage 68 (step S145). In addition, the operation part 67 integrates the Pr component in the predetermined frequency range and outputs the monitor value Prmon to the upper-level controller 80 (step S146).

Returning to the description of FIG. 16, the operation part 67 determines whether or not the control mode is the Pf mode (step S15). When determining that the control mode is the Pf mode (step S15: “Yes”), the operation part 67 sets the power command value Mf for the Pf mode (step S16). When determining that the control mode is not the Pf mode, that is, the control mode is the PL mode (step S15: “No”), the operation part sets the power command value Mf for the PL mode (step S17).

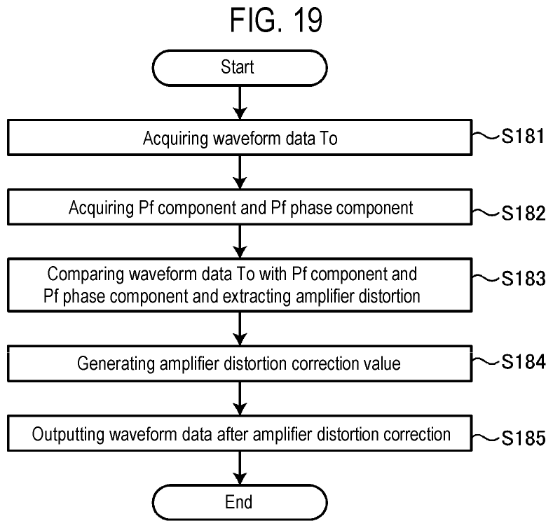

When the power command value Mf is set, the operation part 67 executes an amplifier distortion correction process (step S18). Now, the amplifier distortion correction process will be described with reference to FIG. 19. FIG. 19 is a flowchart illustrating an example of the amplifier distortion correction process.

The comparator 672 of the operation part 67 acquires the waveform data To from the upper-level controller 80 (step S181). The comparator 672 acquires the Pf component and the Pf phase component calculated in the traveling wave power Pf calculation process (step S182). The comparator 672 compares the waveform data To with the Pf component and the Pf phase component, and extracts amplifier distortion (an amplification factor and an amplification phase difference) (step S183). The comparator 672 outputs the extracted amplifier distortion to the first correction value generator 673.

When the amplifier distortion is input from the comparator 672, the first correction value generator 673 generates amplifier distortion correction values for correcting the amplifier distortion based on the amplifier distortion (step S184). The first correction value generator 673 outputs the generated amplifier distortion correction values to the waveform generator 674.

The waveform generator 674 generates waveform data after amplifier distortion correction, based on the waveform data To for waveform setting and the amplifier distortion correction value input from the first correction value generator 673. The waveform generator 674 outputs the generated waveform data after the amplifier distortion correction to the synthesizer 679 (step S185).

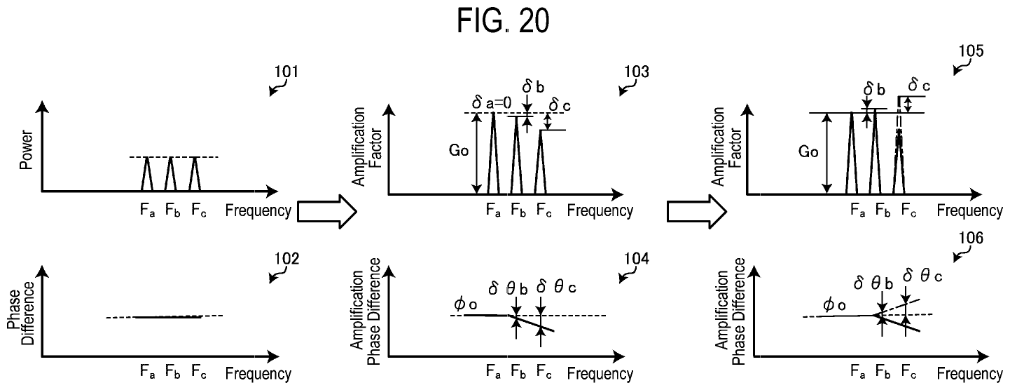

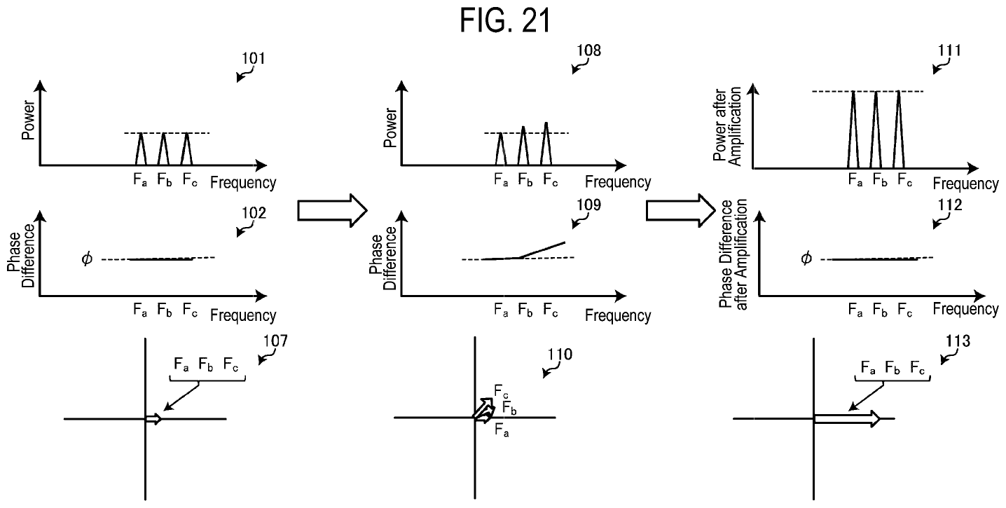

Here, examples of waveforms in the amplifier distortion correction process will be described with reference to FIGS. 20 and 21. FIG. 20 illustrates diagrams illustrating an example of extracting amplifier distortion and generating amplifier distortion correction values. Graphs 101 and 102 illustrated in FIG. 20 represent powers and phase differences of the waveform data To, respectively. Graphs 101 and 102 show frequencies Fₐ, F_{b}, and F_{c} as examples of the plurality of frequencies. In graphs 101 and 102, since the powers at the frequencies Fₐ, F_{b}, and F_{c} are equal to one another, no phase difference is generated.

Graphs 103 and 104 represent amplification factors and amplification phase differences based on the Pf components and Pf phase components. Graph 103 represents that the amplification factors at the frequencies Fₐ, F_{b}, and F_{c} are Go, Go−δb, and Go−δc, respectively, with respect to the reference amplification factor Go. Graph 104 represents that the amplification phase differences at the frequencies Fₐ, F_{b}, and F_{c} are φo, φo−δθb, and φo−δθc, respectively, with respect to the reference phase difference φo.

Graphs 105 and 106 represent respective correction values for the amplification factors and the amplification phase differences in graphs 103 and 104, that is, amplifier distortion correction values. Graph 105 represents that, among the amplifier distortion correction values at the frequencies Fₐ, F_{b}, and F_{c}, the linear correction values (Go+δ)/Go are 1, 1+δb/Go, and 1+δc/Go, respectively. Graph 106 represents that, among the amplifier distortion correction values at the frequencies Fₐ, F_{b}, and F_{c}, the phase correction values −δθ are φo, φo+δθb, and φo+δθc, respectively.

FIG. 21 is a view illustrating examples of powers and phase differences from a set waveform to a corrected output waveform. Graphs 101 and 102 illustrated in FIG. 21 represent the powers and phase differences of the waveform data To, respectively. In addition, graph 107 represents phases and powers at the frequencies Fₐ, F_{b}, and F_{c} in circular coordinates. In graph 107, the phases and powers at the frequencies Fₐ, F_{b}, and F_{c} become equal to one another.

Graphs 108 and 109 represent powers and phase differences of the waveform data after amplifier distortion correction. Graph 110 also represents the phases and powers at the frequencies Fₐ, F_{b}, and F_{c} in circular coordinates. It is recognized in graph 110 that the phases and powers at the frequencies Fₐ, F_{b}, and F_{c} include correction values according to graphs 108 and 109.

Graphs 111 and 112 are represent powers and phase differences of the amplified output waveforms output from the amplifier 65. Graph 113 represents the phases and powers at the frequencies Fₐ, F_{b}, and F_{c} after amplification in circular coordinates. It is recognized in graph 113 that the phases and powers at the frequencies Fₐ, F_{b}, and F_{c} after amplification become equal to one another. As described above, by performing the amplifier distortion correction process, the amplified output waveform may have linear characteristics with respect to the waveform data To of set waveform.

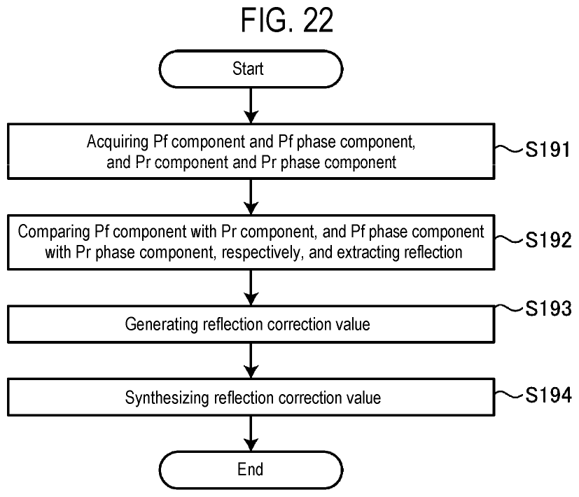

Returning to the description of FIG. 16, the operation part 67 executes a reflection cancellation process (step S19). Here, the reflection cancellation process will be described with reference to FIG. 22. FIG. 22 is a flowchart illustrating an example of the reflection cancellation process.

The comparator 677 of the operation part 67 acquires the Pf components and the Pf phase components calculated in the traveling wave power Pf calculation process, and the Pr components and the Pr phase components calculated in the reflected wave power Pr calculation process (step S191). The comparator 677 compares the Pf components with the Pr components and compares the Pf phase components with the Pr phase components, and extracts reflection (reflectances and reflection phase differences) (step S192). The comparator 677 outputs the extracted reflection to the second correction value generator 678.

When the reflection is input from the comparator 677, the second correction value generator 678 generates reflection correction values that cancel the reflection, based on the reflection (step S193). The second correction value generator 678 outputs the generated reflection correction values to the synthesizer 679.

The synthesizer 679 synthesizes the reflection correction values, which are input from the second correction value generator 678, with the waveform data after amplifier distortion correction, which is input from the waveform generator 674 (step S194). The synthesizer 679 outputs the synthesized waveform data after reflection correction to the modulator 61.

Returning to the description of FIG. 16, the controller 11 determines whether or not to terminate the processing (step S20). When determining not to terminate the processing (step S20: “No”), the controller 11 returns to step S13 and continues to control the frequency-variable power supply 60. When determining to terminate the processing (step S20: “Yes”), the controller stops the frequency-variable power supply 60 to stop outputting the RF power. In addition, the controller 11 controls the plasma processing apparatus 10 to unload the wafer W from the processing container 12 and terminates the processing. As described above, in the plasma processing apparatus 10, reflected waves can be suppressed while omitting a matcher.

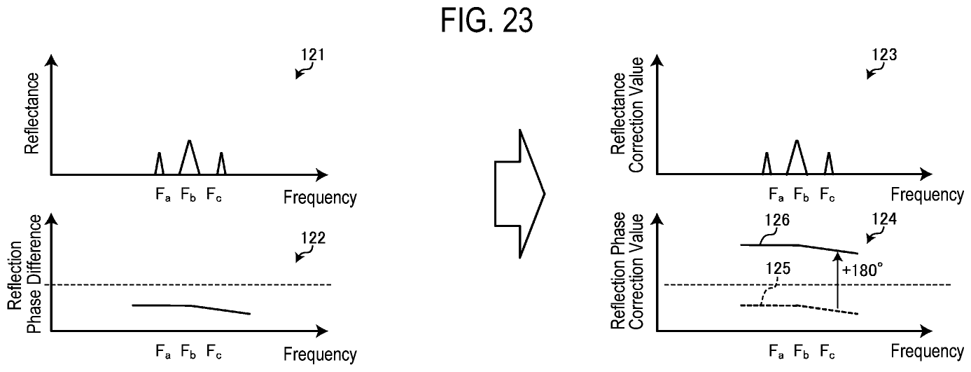

Next, an example of waveforms in the reflection cancellation process will be described with reference to FIGS. 23 to 25. FIG. 23 is a view illustrating an example of extracting the reflection and generating the reflection correction values. Graphs 121 and 122 illustrated in FIG. 23 represent reflectances and reflection phase differences, respectively. Graphs 121 and 122 show frequencies Fₐ, F_{b}, and F_{c} as examples of the plurality of frequencies. In graphs 121 and 122, reflection and reflection phase differences are generated at the frequencies Fₐ, F_{b}, and F_{c}. In addition, in graph 122, the phase of the traveling wave power Pf is indicated by a dashed line.

Graphs 123 and 124 represent reflectance correction values and reflection phase correction values that cancel the reflectances and the reflection phase differences of the graphs 121 and 122. The reflectance correction values of the graph 123 are, for example, values of the same magnitudes as the reflectances. In addition, the reflectance correction values may be obtained by multiplying the reflectances by an arbitrary coefficient. The reflection phase correction values of graph 124 are, for example, reflection phase correction values 126 that differ in phase from reflection phase differences 125 by +180 degrees. The reflection phase correction values may be parameter-adjusted with an arbitrary offset or the like.

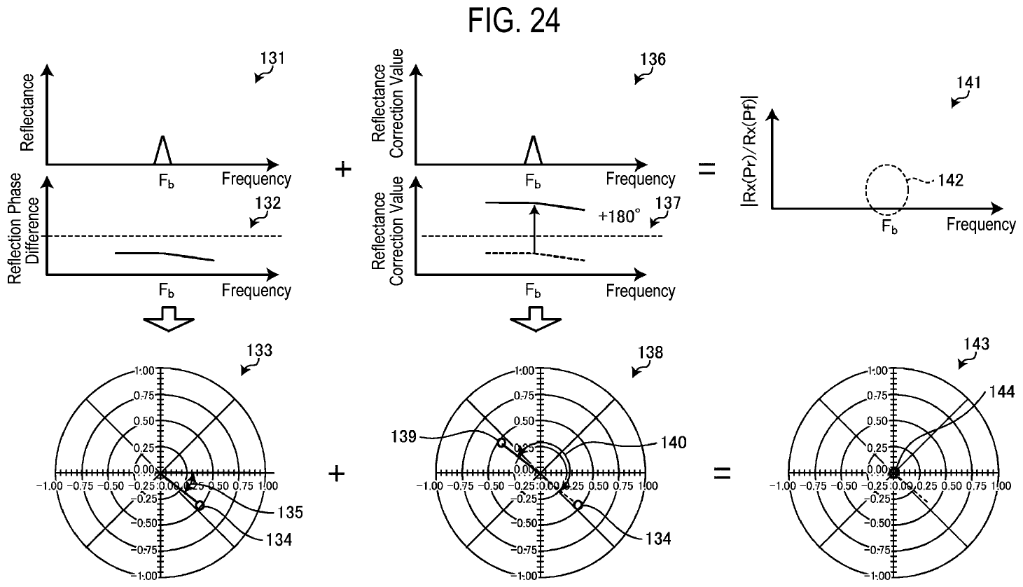

FIG. 24 is a view illustrating an example of synthesizing reflection correction values. In FIG. 24, the frequency F_{b} among the plurality of frequencies will be described as an example. Graphs 131 to 133 illustrated in FIG. 24 represent reflectances, reflection phase differences, and reflection coefficients, respectively. In graphs 131 and 132, the reflection and the reflection phase differences are generated at the frequency F_{b}. In graph 132, the phase of the traveling wave power Pf is indicated by a dashed line. In graph 133, reflection coefficients 134, which are square of the reflectances, are plotted as values with reflection phase differences 135.

Graphs 136 and 137 represent reflectance correction values and reflection phase correction values that cancel the reflectances and the reflection phase differences of the graphs 131 and 132. Graph 138 is obtained by adding the reflectance correction values and the reflection phase correction values to the graph 133. As illustrated in graph 138, reflectance correction values 139 are plotted at positions that differ in phase from the reflection coefficients 134 by reflection phase correction values 140. That is, it can be recognized that the reflectance correction values 139 are located at positions different in phase from the reflection coefficients 134 by +180 degrees.

Graph 141 represents a waveform (|Rx(Pr)/Rx(Pf)|) after reflection correction. In graph 141, as indicated by a region 142, it can be recognized that reflected waves are cancelled. Graph 143 represents the reflection coefficients of the waveform after reflection correction. In graph 143, reflection coefficients 144 are plotted in the center of the graph, so that it can be recognized that the reflection coefficients become zero. In addition, correction is similarly performed at the other frequencies Fₐ and F_{c} at which reflection is generated.

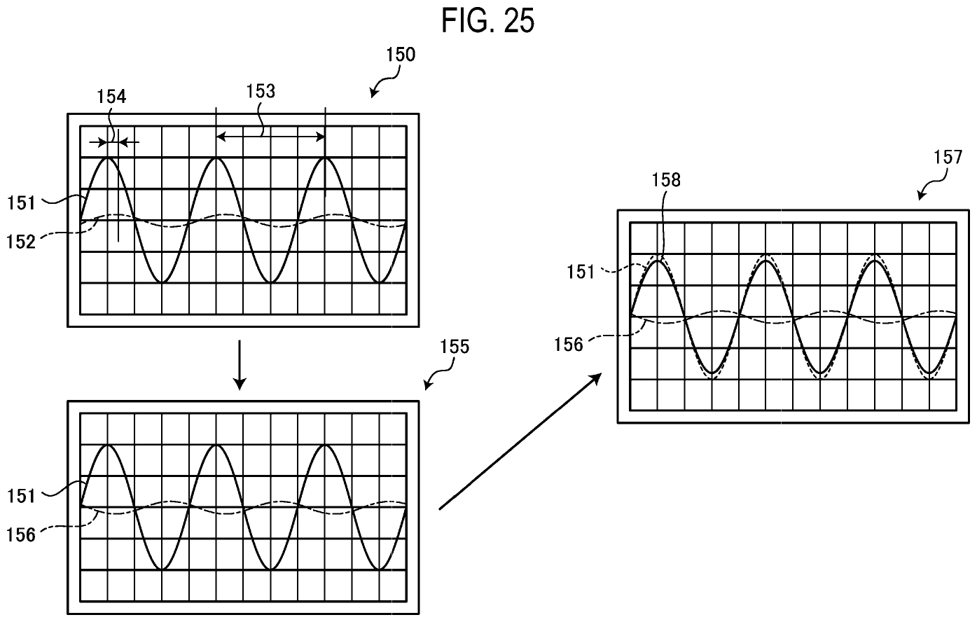

FIG. 25 is a view illustrating an example of synthesizing the traveling wave power Pf and the reflection correction values. Graph 150 in FIG. 25 illustrates a graph 151 corresponding to the monitor value Pfmon of the traveling wave and a graph 152 corresponding to the monitor value Prmon of the reflected waves. In addition, graph 150 also illustrates that graph 152 is delayed by a phase difference 154 with respect to a period 153 of graph 151.

Graph 155 illustrates graph 151, and graph 156 of the reflection correction values that is opposite in phase to graph 152. That is, the graph 152 can be canceled by synthesizing graph 156 with graph 151. Graph 157 illustrates graph 158 obtained by synthesizing graphs 151 and 156. Graph 158 illustrates waveform data after reflection correction, which corresponds to graphs 141 and 143 in FIG. 24. That is, the frequency-variable power supply 60 outputs the waveform data after reflection correction, which is represented by the graph 158, to the modulator 61, thereby performing amplifier distortion correction and reflection cancellation.

### [Modification 1]

In the above-described embodiment, the amplifier distortion is corrected by the first corrector C1 of the operation part 67. However, the amplifier distortion of the amplifier 65 may be measured in advance, and the waveform data To after the amplifier distortion correction are used as the waveform data To for waveform setting. An embodiment in this case will be described as Modification 1. In addition, the same components as those of the plasma processing apparatus 10 of the embodiment are denoted by the same reference numerals, and redundant descriptions of the components and operations are omitted.

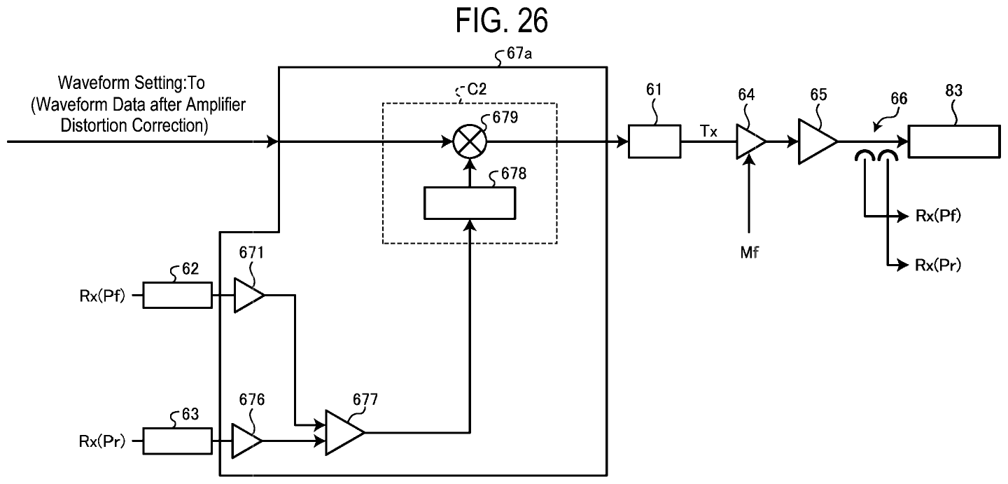

FIG. 26 is a block diagram illustrating an example of a functional configuration from an operation part to a plasma load in Modification 1. As illustrated in FIG. 26, Modification includes an operation part 67a instead of the operation part 67. Compared to the operation part 67, the operation part 67a is not provided with the comparator 672, the first correction value generator 673, and the waveform generator 674, which are included in the first corrector C1, and the waveform data To after amplifier distortion correction is input to the synthesizer 679. In addition, the integrators 675 and 680, the switcher 681, the subtractor 682, the third corrector C3, and the like are omitted from the drawing.

The operation part 67a of Modification 1 executes the traveling wave power Pf calculation process, the reflected wave power Pr calculation process, the power command value Mf setting, and the reflection cancellation process. The operation part 67a outputs the corrected waveform data obtained by performing the reflection cancellation process on the waveform data after amplifier distortion correction to the modulator 61, and outputs the power command value Mf to the preamplifier 64. In addition, the operation part 67a outputs the monitor value Pfmon of the traveling wave power Pf and the monitor value Prmon of the reflected wave power Pr to the upper-level controller 80. With this configuration, the correction values according to the plurality of frequencies can also be calculated by the operation part 67a.

### [Modification 2]

In the above-described embodiment, the directional coupler 66 is used to extract the traveling wave power Pf and the reflected wave power Pr. However, an isolator may be used to separate flows of the traveling wave power Pf and the reflected wave power Pr, and an embodiment in this case will be described as Modification 2. In addition, the same components as those of the plasma processing apparatus 10 of the embodiment are denoted by the same reference numerals, and redundant descriptions of the components and operations are omitted. In Modification 2, the operation part 67a is used as in Modification 1.

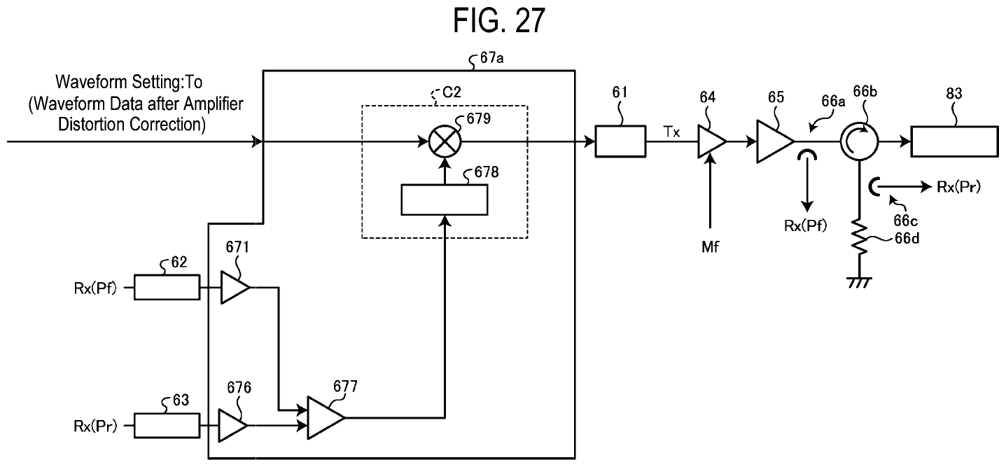

FIG. 27 is a block diagram illustrating an example of a functional configuration from an operation part to a plasma load in Modification 2. As illustrated in FIG. 27, instead of the directional coupler 66, Modification 2 includes directional couplers 66a and 66c, a circulator 66b, and a resistor 66d.

The directional coupler 66a is provided in a transmission path between the amplifier 65 and the circulator 66b, and extracts the traveling wave power Pf. The extracted traveling wave power Rx(Pf) is input to the demodulator 62.

The circulator 66b is provided in a transmission path between the directional coupler 66a and the plasma load 83 on the side of the lower electrode 18, and transmits the traveling wave power Pf input from the directional coupler 66a to the plasma load 83. The circulator 66b separates the reflected wave power Pr by transmitting the reflected wave power Pr input from the plasma load 83 to the resistor 66d. The reflected wave power Pr separated by the circulator 66b is consumed by the resistor 66d.

The directional coupler 66c is provided in a path between the circulator 66b and the resistor 66d, and extracts the reflected wave power Pr. The extracted reflected wave power Rx(Pr) is input to the demodulator 63. With this configuration, by separating flows of the traveling wave power Pf and the reflected wave power Pr by using the circulator 66b, influence of directivity of the directional coupler 66 can be reduced.

### [Modification 3]

In the above-described embodiment, the waveform data after reflection correction is input to the modulator 61 to generate modulated RF signals, which are amplified by the preamplifier 64 and the amplifier 65. However, outphasing may be used in which the waveform data after amplifier distortion correction and the reflection correction values are amplified by different amplifiers and then synthesized. An embodiment in this case will be described as Modification 3. In addition, the same components as those of the plasma processing apparatus 10 of the embodiment are denoted by the same reference numerals, and redundant descriptions of the components and operations are omitted.

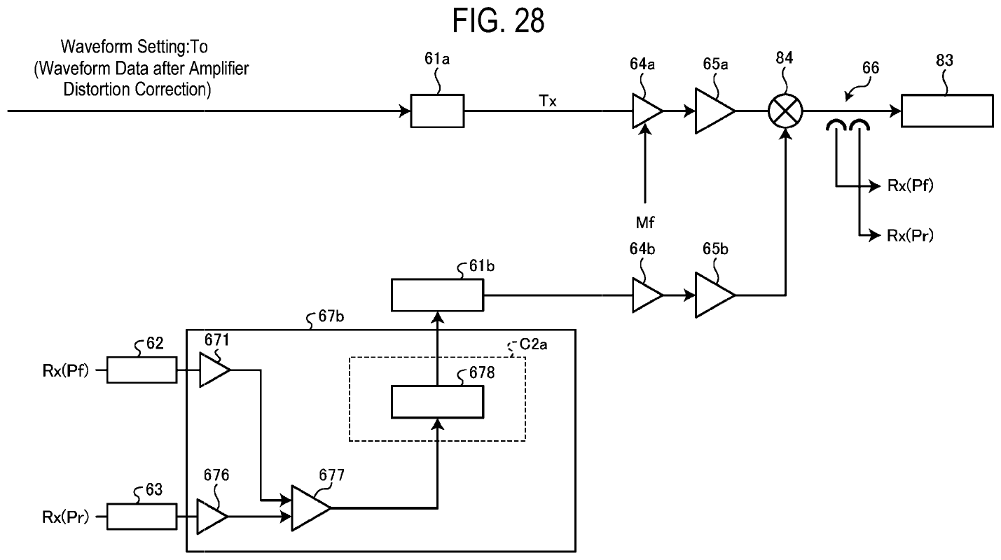

FIG. 28 is a block diagram illustrating an example of a functional configuration from an operation part to a plasma load in Modification 3. As illustrated in FIG. 28, instead of the modulator 61, the preamplifier 64, the amplifier 65, and the operation part 67, Modification 3 includes modulators 61a and 61b, preamplifiers 64a and 64b, amplifiers 65a and 65b, and an operation part 67b. In addition, a synthesizer 84 is provided between the amplifier 65a and the directional coupler 66. As in Modifications 1 and 2, Modification 3 uses previously prepared waveform data To after amplifier distortion correction.

The operation part 67b includes a second corrector C2a without having the synthesizer 679, instead of the second corrector C2 of the operation part 67a of Modification 1. That is, Modification 3 is modified such that waveform synthesis is performed in a rear stage of the amplifiers 65a and 65b. Since other components are the same as those of the operation part 67a, description thereof is omitted. The operation part 67b outputs the reflection correction value generated by the second correction value generator 678 to the modulator 61b.

The modulator 61a generates a modulated RF signal based on the waveform data To after amplifier distortion correction, which is input from the upper-level controller 80, and outputs the modulated RF signal to the preamplifier 64a. The modulator 61b generates a modulated RF signal based on the reflection correction value input from the operation part 67b, and outputs the modulated RF signal to the preamplifier 64b.

The preamplifier 64a amplifies the RF signal input from the modulator 61a with an amplification factor according to the power command value Mf input from the operation part 67b, and outputs the amplified signal to the amplifier 65a. The preamplifier 64b amplifies the RF signal input from the modulator 61b and outputs the amplified signal to the amplifier 65b.

The amplifier 65a amplifies the RF waves input from the preamplifier 64a by using a nonlinear region as well, and outputs the amplified RF waves to the synthesizer 84. The amplifier 65b amplifies the RF waves input from the preamplifier 64b by using a linear region only, and outputs the amplified RF waves to the synthesizer 84.

The synthesizer 84 synthesizes the RF waves input from the amplifier 65a and the RF waves input from the amplifier 65b by outphasing, and outputs the synthesized RF waves to the plasma load 83 on the side of the lower electrode 18 as the RF power for plasma generation. By synthesizing the RF power for plasma generation by outphasing as described above, efficiency of RF conversion in the amplifier 65 can be improved.

As described above, according to the present embodiment, the frequency-variable power supply 60 is a frequency-variable power supply that outputs RF waves having a set frequency, and includes an operation part 67 that calculates a correction value according to a plurality of frequencies which falls within a frequency range that can be output. As a result, reflected waves can be suppressed while omitting a matcher.

According to the present embodiment, the correction value is at least one of the amplifier distortion correction value, the reflection correction value, or the power correction value. As a result, amplifier distortion, reflection, and RF power can be corrected.

According to the present embodiment, the correction value is a correction value for at least one of the amplitude or the phase of the RF waves. As a result, amplifier distortion can be corrected, and reflection can be canceled.

According to the present embodiment, the frequency-variable power supply 60 further includes the directional coupler 66 provided between the frequency-variable power supply 60 and a load. The operation part 67 calculates the amplifier distortion correction value based on a comparison between traveling waves output from the directional coupler 66 and set waveform data. As a result, the amplifier distortion of the RF power for plasma generation, which is being output, can be corrected.

According to the present embodiment, the operation part 67 calculates the amplifier distortion correction value based on an amplification factor and an amplification phase difference of the traveling waves with respect to the waveform data. As a result, the amplifier distortion of the RF power for plasma generation, which is being output, can be corrected.

According to the present embodiment, the operation part 67 calculates the reflection correction value based on a comparison between the traveling waves and the reflected waves output from the directional coupler 66. As a result, the reflection of the RF power for plasma generation, which is being output, can be canceled.

According to the present embodiment, the operation part 67 calculates the reflection correction value based on the reflectance and the reflection phase difference of the reflected waves. As a result, the reflection of the RF power for plasma generation, which is being output, can be canceled.

According to the present embodiment, the reflection correction value has a phase obtained by inverting the phase of the reflected waves by 180 degrees. As a result, the reflection of the RF power for plasma generation, which is being output, can be canceled.

According to the present embodiment, when controlling the input power to be constant, the operation part 67 calculates the power correction value based on the traveling waves, and when controlling the effective power to be constant, the operation part 67 calculates the power correction value based on the difference between the traveling waves and the reflected waves. As a result, the RF power for plasma generation can be controlled such that the input power is constant or the effective power is constant.

According to the present embodiment, the frequency-variable power supply 60 further includes the first demodulator (the demodulator 62) that demodulates the traveling waves, and the second demodulator (the demodulator 63) that demodulates the reflected waves. The traveling waves are traveling waves corrected with a correction value corresponding to the first demodulator, and the reflected waves are reflected waves corrected with a correction value corresponding to the second demodulator. As a result, a feedback control can be performed to correct the amplifier distortion and to cancel the reflection of the RF power for plasma generation, which is being output.

According to the present embodiment, the frequency-variable power supply 60 further includes the modulator 61 that generates RF waves, the amplifier (the preamplifier 64 and the amplifier 65) that amplifies the generated RF waves, and the directional coupler 66 provided between the amplifier and the load. The operation part 67 corrects the set waveform data with the correction value, inputs the corrected data to the modulator 61, and updates the correction value based on the traveling waves and the reflected waves output from the directional coupler 66. As a result, the amplifier distortion correction, the reflection cancellation, and the power correction of the RF power for plasma generation, which is being output, can be performed.

It is to be considered that the embodiments disclosed herein are exemplary in all respects and not restrictive. Various types of omissions, substitutions, and changes may be made to the above-described embodiment without departing from the scope and spirit of the appended claims.

In addition, in the above-described embodiments, as an example of the frequency of the frequency-variable power supply 60, a frequency within a high frequency (HF) band has been described, but the present disclosure is not limited thereto. For example, a very high frequency (VHF) band such as 40 MHz or an ultra-high frequency (UHF) band (including microwaves) such as 2.45 GHz or higher may be used. In addition, in a frequency-variable power supply of 2.45 GHz±50 MHz, for example, the plurality of frequencies may be a broadband having 1,000 or more peaks in a 10 MHz bandwidth. That is, the frequency-variable power supply 60 may be, for example, a broadband power supply capable of outputting RF power having 100 or more peaks at intervals of 100 kHz.

In addition, in the above-described embodiments, the plasma processing apparatus 10, which performs a processing such as film formation on the wafer W by using capacitively coupled plasma as a plasma source, has been described as an example, but the technology disclosed herein is not limited thereto. The plasma source is not limited to capacitively coupled plasma as long as the apparatus performs a processing on the wafer W by using plasma. Any plasma source such as inductively coupled plasma, microwave plasma such as electron-cyclotron resonance (ECR) microwave plasma or surface-wave microwave plasma, or magnetron plasma may be used.

In addition, the present disclosure may also take the following configurations.
(1) A frequency-variable power supply that outputs RF waves of a set frequency, including an operation part configured to calculate a correction value according to each of a plurality of frequencies within an outputtable frequency range.
(2) The frequency-variable power supply set forth in item (1), wherein the correction value is at least one of an amplifier distortion correction value, a reflection correction value, or a power correction value.
(3) The frequency-variable power supply set forth in item (2), wherein the correction value is a correction value for at least one of an amplitude or a phase of the RF waves.
(4) The frequency-variable power supply set forth in item (2) or (3), further including a directional coupler provided between the frequency-variable power supply and a load,
wherein the operation part is configured to calculate the amplifier distortion correction value based on a comparison between traveling waves output from the directional coupler and set waveform data.
(5) The frequency-variable power supply set forth in item (4), wherein the operation part is configured to calculate the amplifier distortion correction value based on an amplification factor and an amplification phase difference of the traveling waves with respect to the set waveform data.
(6) The frequency-variable power supply set forth in item (4) or (5), wherein the operation part is configured to calculate the reflection correction value based on a comparison between the traveling waves and reflected waves output from the directional coupler.
(7) The frequency-variable power supply set forth in item (6), wherein the operation part is configured to calculate the reflection correction value based on a reflectance and a reflection phase difference of the reflected waves.
(8) The frequency-variable power supply set forth in item (7), wherein the reflection correction value has a phase obtained by inverting a phase of the reflected waves by 180 degrees.
(9) The frequency-variable power supply set forth in any one of items (6) to (8), wherein the operation part is configured to calculate the power correction value based on the traveling waves when controlling an input power to be constant and calculate the power correction value based on a difference between the traveling waves and the reflected waves when controlling an effective power to be constant.
(10) The frequency-variable power supply set forth in any one of items (6) to (9), further including:
a first demodulator configured to demodulate the traveling waves; and
a second demodulator configured to demodulate the reflected waves,
wherein the traveling waves are traveling waves corrected with a correction value corresponding to the first demodulator, and
wherein the reflected waves are reflected waves corrected with a correction value corresponding to the second demodulator.
(11) The frequency-variable power supply set forth in any one of items (1) to (10), further including:
a modulator configured to generate the RF waves;
an amplifier configured to amplify the generated RF waves; and
a directional coupler provided between the amplifier and a load,
wherein the operation part is configured to correct set waveform data with the correction value, to input the corrected set waveform data to the modulator, and to update the correction value based on traveling waves and reflected waves output from the directional coupler.
(12) A plasma processing apparatus including:
a processing container;
an electrode provided within the processing container; and
a frequency-variable power supply configured to output RF waves having a set frequency to the electrode,
wherein the frequency-variable power supply includes an operation part configured to calculate a correction value according to each of a plurality of frequencies within an outputtable frequency range.

According to the present disclosure, reflected waves can be suppressed while omitting a matcher.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A frequency-variable power supply that outputs radio-frequency (RF) waves of a set frequency, comprising an operation part configured to calculate a correction value according to each of a plurality of frequencies within an outputtable frequency range.

2. The frequency-variable power supply of claim 1, wherein the correction value is at least one of an amplifier distortion correction value, a reflection correction value, or a power correction value.

3. The frequency-variable power supply of claim 2, wherein the correction value is a correction value for at least one of an amplitude or a phase of the RF waves.

4. The frequency-variable power supply of claim 2, further comprising a directional coupler provided between the frequency-variable power supply and a load,
wherein the operation part is configured to calculate the amplifier distortion correction value based on a comparison between traveling waves output from the directional coupler and set waveform data.

5. The frequency-variable power supply of claim 4, wherein the operation part is configured to calculate the amplifier distortion correction value based on an amplification factor and an amplification phase difference of the traveling waves with respect to the set waveform data.

6. The frequency-variable power supply of claim 4, wherein the operation part is configured to calculate the reflection correction value based on a comparison between the traveling waves and reflected waves output from the directional coupler.

7. The frequency-variable power supply of claim 6, wherein the operation part is configured to calculate the reflection correction value based on a reflectance and a reflection phase difference of the reflected waves.

8. The frequency-variable power supply of claim 7, wherein the reflection correction value has a phase obtained by inverting a phase of the reflected waves by 180 degrees.

9. The frequency-variable power supply of claim 6, wherein the operation part is configured to calculate the power correction value based on the traveling waves when controlling an input power to be constant, and calculate the power correction value based on a difference between the traveling waves and the reflected waves when controlling an effective power to be constant.

10. The frequency-variable power supply of claim 6, further comprising:
a first demodulator configured to demodulate the traveling waves; and
a second demodulator configured to demodulate the reflected waves,
wherein the traveling waves are traveling waves corrected with a correction value corresponding to the first demodulator, and
wherein the reflected waves are reflected waves corrected with a correction value corresponding to the second demodulator.

11. The frequency-variable power supply of claim 1, further comprising:
a modulator configured to generate the RF waves;
an amplifier configured to amplify the generated RF waves; and
a directional coupler provided between the amplifier and a load,
wherein the operation part is configured to: correct set waveform data with the correction value; input the corrected set waveform data to the modulator; and update the correction value based on traveling waves and reflected waves output from the directional coupler.

12. A plasma processing apparatus comprising:
a processing container;
an electrode provided in the processing container; and
a frequency-variable power supply configured to output RF waves of a set frequency to the electrode,
wherein the frequency-variable power supply comprises an operation part configured to calculate a correction value according to each of a plurality of frequencies within an outputtable frequency range.
